(19) United States
(12) Patent Application Publication
(10) Pub. No.: US 2026/0173880 A1
(43) Pub. Date: Jun. 18, 2026

(54) SEMICONDUCTOR DEVICE HAVING GUARD RING

(71) Applicant: SK hynix Inc., Gyeonggi-do (KR)

(72) Inventor: Heon Yong CHANG, Gyeonggi-do (KR)

(21) Appl. No.: 19/185,277

(22) Filed: Apr. 22, 2025

(30) Foreign Application Priority Data
Dec. 18, 2024 (KR) 10-2024-0190187

(51) Int. Cl. H01L 23/00; H01L 23/58; H01L 25/07

(52) U.S. Cl. CPC H10W 42/00; H10W 90/00; H10W 80/312; H10W 80/327; H10W 90/26; H10W 90/297; H10W 90/792

(57) ABSTRACT

A semiconductor device may comprise a first circuit structure having a first active area and a first guard ring area and a second circuit structure on the first circuit structure and having a second active area and a second guard ring area. The first circuit structure may include a lower guard ring in the first guard ring area, and a lower insulative bonding layer extended in both the first active area and the first guard ring area. The second circuit structure may include an upper insulative bonding layer on the lower insulative bonding layer, and an upper guard ring. The lower insulative bonding layer may be disposed in the first guard ring area between the lower guard ring and the upper guard ring. The upper insulative bonding layer may be disposed in the second guard ring area between the lower guard ring and the upper guard ring.

### CROSS-REFERENCE TO RELATED APPLICATION

This application claims priority from Korean Patent Application No. 10-2024-0190187, filed on Dec. 18, 2024, which is hereby incorporated by reference for all purposes as if fully set forth herein.

### BACKGROUND

### Field

Embodiments of the present disclosure relate generally to semiconductor technology and, more particularly, to a semiconductor device having a guard ring and a method for forming the same.

### Description of Related Art

Recently, for higher integration of semiconductor devices, a technology has been proposed which includes bonding a wafer having memory cells on another wafer having peripheral circuits. However, the bonding between the wafers needs to be adequately strong and provide excellent electrical connection between the memory cells to the peripheral circuits. Further improvements are needed in these areas.

### BRIEF SUMMARY

Embodiments of the present disclosure may provide a semiconductor device having a guard ring and a method for forming the same.

Embodiments of the present disclosure are not limited to those set forth herein, and other unmentioned embodiments would be apparent to one of ordinary skill in the art from the following description.

Embodiments of the present disclosure may provide a semiconductor device comprising a first circuit structure having a first active area and a first guard ring area and a second circuit structure bonded on the first circuit structure and having a second active area and a second guard ring area. The first circuit structure may include a lower insulation layer, a lower line disposed in the lower insulation layer in the first active area, a lower guard ring disposed in the lower insulation layer in the first guard ring area, a lower insulative bonding layer disposed on the lower insulation layer, the lower insulative bonding layer extending in both the first active area and the first guard ring area, and a lower bonding pad disposed in the lower insulative bonding layer in the first active area, and connected to the lower line. The second circuit structure may include an upper insulative bonding layer disposed in the second active area and the second guard ring area, and bonded on the lower insulative bonding layer, an upper bonding pad disposed in the upper insulative bonding layer in the second active area, and bonded on the lower bonding pad, an upper insulation layer on the upper insulative bonding layer, an upper line disposed in the upper insulation layer in the second active area, and connected to the upper bonding pad, and an upper guard ring disposed in the upper insulation layer in the second guard ring area. The lower insulative bonding layer may be disposed in the first guard ring area between the lower guard ring and the upper guard ring. The upper insulative bonding layer may be disposed in the second guard ring area between the lower guard ring and the upper guard ring.

Embodiments of the present disclosure may provide a semiconductor device comprising a first circuit structure having a first active area and a first guard ring area and a second circuit structure bonded to the first circuit structure and having a second active area and a second guard ring area. The first circuit structure may include a lower insulation layer, a lower line disposed in the lower insulation layer in the first active area, a lower guard ring disposed in the lower insulation layer in the first guard ring area, and a lower insulative bonding layer disposed in the first active area and the first guard ring area, and formed on the lower insulation layer. The second circuit structure may include an upper insulative bonding layer disposed in the second active area and the second guard ring area, and bonded on the lower insulative bonding layer, an upper insulation layer on the upper insulative bonding layer, an upper line disposed in the upper insulation layer in the second active area, and an upper guard ring disposed in the upper insulation layer in the second guard ring area. The lower insulative bonding layer may extend into the first guard ring area between the lower guard ring and the upper guard ring. The upper insulative bonding layer may extend into the second guard ring area between the lower guard ring and the upper guard ring.

Embodiments of the present disclosure may provide a semiconductor device comprising a first circuit structure having a first active area and a first guard ring area and a second circuit structure bonded on the first circuit structure and having a second active area and a second guard ring area. The first circuit structure may include a lower transistor on a substrate, a lower insulation layer on the substrate and the lower transistor, a lower line disposed in the lower insulation layer in the first active area, a lower guard ring disposed in the lower insulation layer in the first guard ring area, a lower insulative bonding layer disposed in the first active area and the first guard ring area, and formed on the lower insulation layer, and a lower bonding pad disposed in the lower insulative bonding layer in the first active area, and connected to the lower line. The second circuit structure may include an upper insulative bonding layer disposed in the second active area and the second guard ring area, and bonded on the lower insulative bonding layer, an upper bonding pad disposed in the upper insulative bonding layer in the second active area, and bonded on the lower bonding pad, an upper insulation layer on the upper insulative bonding layer, an upper line disposed in the upper insulation layer in the second active area, and connected to the upper bonding pad, a stack structure disposed in the upper insulation layer in the second active area, a channel structure penetrating the stack structure, a common source line disposed on the stack structure and connected to the channel structure, and an upper guard ring disposed in the upper insulation layer in the second guard ring area. The lower insulative bonding layer may extend into the first guard ring area between the lower guard ring and the upper guard ring. The upper insulative bonding layer may extend into the second guard ring area between the lower guard ring and the upper guard ring.

According to an embodiment of the present disclosure, there may be provided a semiconductor device having a guard ring and a method for forming the same.

The embodiments of the present disclosure are not limited to the foregoing embodiments, and other embodiments will be apparent to one of ordinary skill in the art from the following detailed description.

### BRIEF DESCRIPTION OF DRAWINGS

The embodiments of the present disclosure will be more fully understood from the following detailed description and the accompanying drawings, which are provided for illustration only and are not intended to limit the embodiments.

FIG. 1 is a cross-sectional view illustrating a semiconductor device according to an embodiment of the present disclosure;

FIGS. 2 to 5 are plan views illustrating a semiconductor device according to an embodiment of the present disclosure;

FIG. 6 is a view illustrating a portion of FIG. 1;

FIG. 7 is a cross-sectional view illustrating a semiconductor device according to an embodiment of the present disclosure; and

FIGS. 8 to 20 are cross-sectional views illustrating a method for forming a semiconductor device according to embodiments of the present disclosure.

### DETAILED DESCRIPTION

Hereinafter, embodiments of the present disclosure are described in detail with reference to the accompanying drawings. In assigning reference numerals to components of each drawing, the same components may be assigned the same numerals even when they are shown on different drawings. When it is determined that the subject matter of the present disclosure will be unclear, the details of the known art or functions may be skipped. As used herein, when a component “includes,” “has,” or “is composed of” another component, the component may have other components unless the term “only” is used with the terms “includes, has, or is composed of”. As used herein, the singular forms “a”, “an” and “the” are intended to include the plural forms as well, unless the context clearly indicates otherwise.

Such labels as “first,” “second,” “A,” “B,” “(a),” and “(b),” may be used in describing the components of the present disclosure. These labels are provided merely to distinguish a component from another, and the essence, order, or number of the components are not limited by the labels.

In describing the positional relationship between components, when two or more components are described as “connected”, “coupled” or “linked”, the two or more components may be directly “connected”, “coupled” or “linked””, or another component may intervene. Here, the other component may be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

Hereinafter, various embodiments of the present disclosure are described in detail with reference to the accompanying drawings.

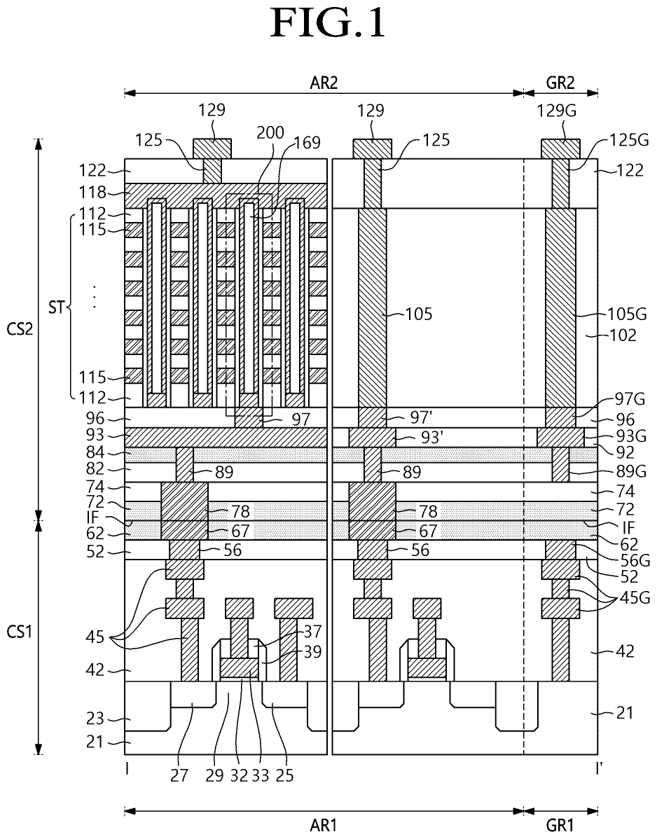

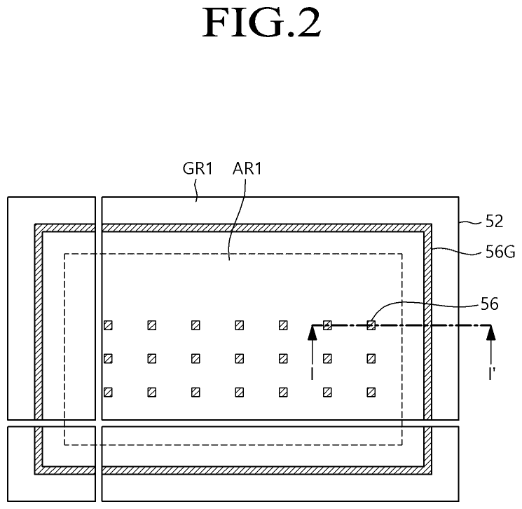

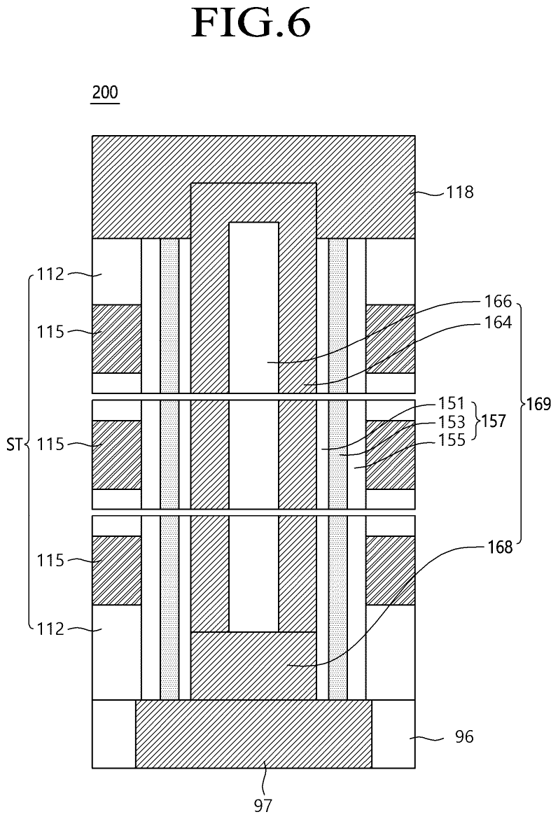

FIG. 1 is a cross-sectional view illustrating a semiconductor device according to an embodiment of the present disclosure. FIGS. 2 to 5 are plan views illustrating a semiconductor device according to an embodiment of the present disclosure. FIG. 6 is a view illustrating a portion 200 of FIG. 1. In an embodiment, FIG. 1 may be a cross-sectional view taken along the cutting line I-I′ of FIGS. 2 to 5. In an embodiment, a semiconductor device according to an embodiment of the present disclosure may include a non-volatile memory device such as a flash memory.

Referring to FIG. 1, a semiconductor device according to an embodiment of the present disclosure may include a first circuit structure CS1 and a second circuit structure CS2 bonded on the first circuit structure CS1. The first circuit structure CS1 may include a first active area AR1 and a first guard ring area GR1. The first guard ring area GR1 may be continuous to a side surface of the first active area AR1. The second circuit structure CS2 may include a second active area AR2 and a second guard ring area GR2. The second guard ring area GR2 may be continuous to a side surface of the second active area AR2. The second guard ring area GR2 may overlap with the first guard ring area GR1. The second guard ring area GR2 may overlap with the first guard ring area GR1.

The first circuit structure CS1 may include a first substrate 21, an element isolation layer 23, a lower source area 25, a lower drain area 27, a lower channel area 29, a lower gate insulation layer 32, a lower gate electrode 33, a gate capping layer 37, a gate spacer 39, a first lower insulation layer 42, a lower line 45, a lower line guard ring 45G, a second lower insulation layer 52, a lower contact plug 56, a lower contact guard ring 56G, a lower insulative bonding layer 62, and a lower bonding pad 67. The lower line 45 may be disposed in the first active area AR1 while the lower guard ring 45G may be disposed in the first guard ring area GR1. The lower insulative bonding layer 62 extends in both the first active area AR1 and the first guard ring area GR1.

The element isolation layer 23 may be disposed in the first substrate 21. The first lower insulation layer 42, the second lower insulation layer 52, and the lower insulative bonding layer 62 may be sequentially stacked on the first substrate 21 and the element isolation layer 23. Each of the first substrate 21, the element isolation layer 23, the first lower insulation layer 42, the second lower insulation layer 52, and the lower insulative bonding layer 62 may extend from the first active area AR1 to the first guard ring area GR1. The lower source area 25, the lower drain area 27, the lower channel area 29, the lower gate insulation layer 32, the lower gate electrode 33, the gate capping layer 37, the gate spacer 39, the lower line 45, the lower contact plug 56, and the lower bonding pad 67 may be disposed in the first active area AR1. The lower line guard ring 45G and the lower contact guard ring 56G may be disposed in the first guard ring area GR1.

The second circuit structure CS2 may include an upper insulative bonding layer 72, a first upper insulation layer 74, an upper bonding pad 78, a second upper insulation layer 82, a third upper insulation layer 84, a first upper contact plug 89, a first upper contact guard ring 89G, a fourth upper insulation layer 92, a bit line 93, a first upper line 93′, a first upper line guard ring 93G, a fifth upper insulation layer 96, a bit contact plug 97′, a second upper contact plug 97′, a second upper contact guard ring 97G, a sixth upper insulation layer 102, a stack structure ST, a third upper contact plug 105, a third upper contact guard ring 105G, a common source line 118, a seventh upper insulation layer 122, a fourth upper contact plug 125, a fourth upper contact guard ring 125G, a second upper line 129, a second upper line guard ring 129G, and a plurality of channel structures 169. The stack structure ST may include a plurality of molding layers 112 and a plurality of horizontal electrodes 115 that are alternately stacked.

The upper insulative bonding layer 72, the first upper insulation layer 74, the second upper insulation layer 82, the third upper insulation layer 84, the fourth upper insulation layer 92, the fifth upper insulation layer 96, the sixth upper insulation layer 102, and the seventh upper insulation layer 122 may be sequentially stacked on the first circuit structure CS1. The upper insulative bonding layer 72 may be bonded on the lower insulative bonding layer 62. An interface IF may be formed between the upper insulative bonding layer 72 and the lower insulative bonding layer 62. Each of the upper insulative bonding layer 72, the first upper insulation layer 74, the second upper insulation layer 82, the third upper insulation layer 84, the fourth upper insulation layer 92, the fifth upper insulation layer 96, the sixth upper insulation layer 102, and the seventh upper insulation layer 122 may extend from the second active area AR2 to the second guard ring area GR2.

The upper bonding pad 78, the first upper contact plug 89, the bit line 93, the first upper line 93′, the bit contact plug 97, the second upper contact plug 97′, the stack structure ST, the third upper contact plug 105, the common source line 118, the fourth upper contact plug 125, the second upper line 129, and the plurality of channel structures 169 may be disposed in the second active area AR2. The first upper contact guard ring 89G, the first upper line guard ring 93G, the second upper contact guard ring 97G, the third upper contact guard ring 105G, the fourth upper contact guard ring 125G, and the second upper line guard ring 129G may be disposed in the second guard ring area GR2.

Referring to FIG. 2, the first guard ring area GR1 may surround an edge of the first active area AR1. The second lower insulation layer 52 may be disposed in the first active area AR1 and the first guard ring area GR1. A plurality of lower contact plugs 56 may be disposed in the second lower insulation layer 52 in the first active area AR1. The lower contact guard ring 56G may be disposed in the second lower insulation layer 52 in the first guard ring area GR1. The lower contact guard ring 56G may surround the first active area AR1.

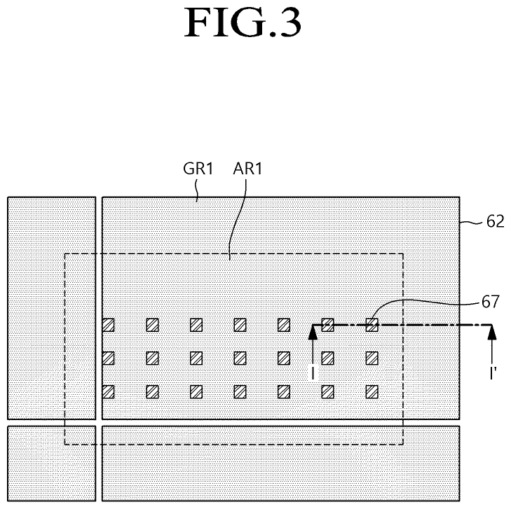

Referring to FIG. 3, the lower insulative bonding layer 62 may be disposed in the first active area AR1 and the first guard ring area GR1. A plurality of lower bonding pads 67 may be disposed in the lower insulative bonding layer 62 in the first active area AR1 spaced apart from each other. The lower insulative bonding layer 62 may fully cover the first guard ring area GR1.

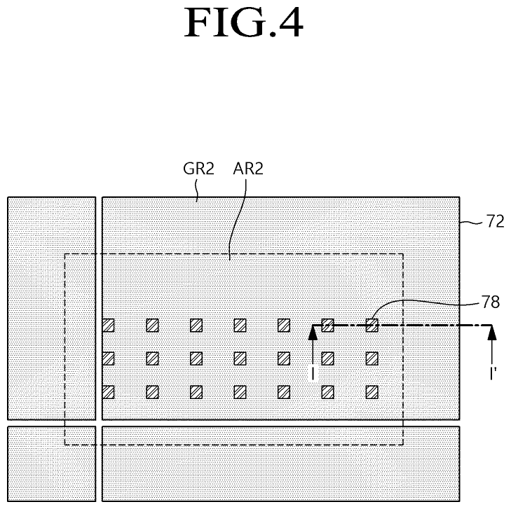

Referring to FIG. 4, the second guard ring area GR2 may surround an edge of the second active area AR2. The upper insulative bonding layer 72 may be disposed in the second active area AR2 and the second guard ring area GR2. A plurality of upper bonding pads 78 may be disposed in the upper insulative bonding layer 72 in the second active area AR2. The upper insulative bonding layer 72 may fully cover the second guard ring area GR2.

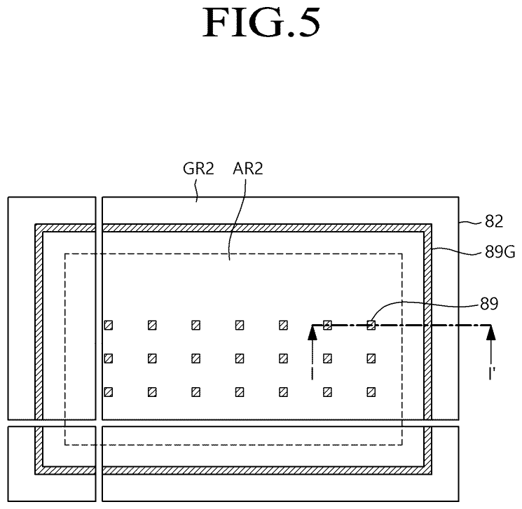

Referring to FIG. 5, the second upper insulation layer 82 may be disposed in the second active area AR2 and the second guard ring area GR2. A plurality of first upper contact plugs 89 may be disposed in the second upper insulation layer 82 in the second active area AR2. The first upper contact guard ring 89G may be disposed in the second upper insulation layer 82 in the second guard ring area GR2. The first upper contact guard ring 89G may surround the second active area AR2.

Referring to FIG. 6, a semiconductor device 200 according to an embodiment of the present disclosure may include a stack structure ST, a fifth upper insulation layer 96, a bit contact plug 97, a common source line 118, and a channel structure 169. The stack structure ST may include a plurality of molding layers 112 and a plurality of horizontal electrodes 115 that are alternately stacked. Each of the uppermost layer and the lowermost layer of the stack structure ST may be one of the plurality of molding layers 112. The common source line 118 may be disposed on the stack structure ST.

The channel structure 169 may include an information storage pattern 157, a channel pattern 164, a core layer 166, and a drain pad 168. The information storage pattern 157 may include a tunnel layer 151, a charge trap layer 153, and a blocking layer 155. The channel structure 169 may pass through the stack structure ST in a vertical direction and extend into the common source line 118. The core layer 166 may pass through the stack structure ST and may extend into the common source line 118, meaning that its top surface may be above the bottom surface of the common source line 118. However, the core layer 166 may not contact the common source line 118 because it is surrounded by the channel pattern 164. More specifically, the channel pattern 164 may surround the side surface and the top surface (also referred to as upper surface) of the core layer 166. The channel pattern 164 may extend into the common source line 118. The channel pattern 164 may directly contact the common source line 118.

The information storage pattern 157 may surround a side surface of the channel pattern 164. The channel pattern 164 may be disposed between the information storage pattern 157 and the core layer 166. The information storage pattern 157 may be disposed between the channel pattern 164 and the stack structure ST. In an embodiment, the tunnel layer 151 may be disposed on a side surface of the channel pattern 164. The tunnel layer 151 may contact the channel pattern 164. The tunnel layer 151 may be disposed between the channel pattern 164 and the charge trap layer 153. The tunnel layer 151 may contact the charge trap layer 153.

The charge trap layer 153 may be disposed on the side surface of the tunnel layer 151. The charge trap layer 153 may be disposed between the tunnel layer 151 and the blocking layer 155. The blocking layer 155 may be disposed on the side surface of the charge trap layer 153. The blocking layer 155 may be disposed between the charge trap layer 153 and the stack structure ST. The blocking layer 155 may extend between the charge trap layer 153 and the plurality of horizontal electrodes 115 and between the charge trap layer 153 and the plurality of molding layers 112.

The drain pad 168 may be disposed on the lower surfaces (also referred to as the bottom surfaces) of the core layer 166 and the channel pattern 164. The drain pad 168 may directly contact the channel pattern 164. The fifth upper insulation layer 96 may be disposed on the lower surface of the stack structure ST and the channel structure 169. The bit contact plug 97 may be disposed in the fifth upper insulation layer 96. The bit contact plug 97 may be connected to the drain pad 168.

In an embodiment, the plurality of horizontal electrodes 115 may include a plurality of word lines, a plurality of select lines, and at least one gate induced drain leakage (GIDL) control line. Memory cells may be formed at intersections of the channel structure 169 and the plurality of word lines. At least one of the plurality of horizontal electrodes 115 adjacent to the common source line 118 may correspond to a source select line. At least one of the plurality of horizontal electrodes 115 adjacent to the drain pad 168 may correspond to a drain select line. One of the plurality of horizontal electrodes 115 adjacent to the common source line 118 and/or one of the plurality of horizontal electrodes 115 adjacent to the drain pad 168 may correspond to a GIDL control line. A plurality of word lines may be disposed between at least one drain select line and at least one source select line among the plurality of horizontal electrodes 115.

Referring back to FIGS. 1 to 6, the first substrate 21 may be disposed in the first active area AR1 and the first guard ring area GR1. The first substrate 21 may extend from the first active area AR1 to the first guard ring area GR1. The element isolation layer 23 may be disposed to reach a predetermined depth from the upper surface of the first substrate 21. The lower source area 25, the lower drain area 27, and the lower channel area 29 may be limited to the inside of the first substrate 21 by the element isolation layer 23. The lower source area 25 and the lower drain area 27 may be spaced apart from each other. The lower channel area 29 may be limited between the lower source area 25 and the lower drain area 27.

The lower gate insulation layer 32 may be disposed on the lower channel area 29. The lower gate electrode 33 may be disposed on the lower gate insulation layer 32. The gate capping layer 37 may be disposed on the lower gate electrode 33. The gate spacer 39 may be disposed on side surfaces of the gate capping layer 37 and the lower gate electrode 33. The first lower insulation layer 42 may cover the first substrate 21, the element isolation layer 23, the lower source area 25, the lower drain area 27, the lower channel area 29, the lower gate insulation layer 32, the lower gate electrode 33, the gate capping layer 37, and the gate spacer 39.

The lower line 45 and the lower line guard ring 45G may be disposed in the first lower insulation layer 42. The lower line 45 may include a plurality of horizontal lines, a plurality of vertical lines, or a combination thereof. A corresponding one among the lower lines 45 may pass through the first lower insulation layer 42 to contact the lower drain area 27. Another corresponding one among the lower lines 45 may pass through the first lower insulation layer 42 to contact the lower source area 25. Another corresponding one among the lower lines 45 may pass through the first lower insulation layer 42 and the gate capping layer 37 to contact the lower gate electrode 33.

The lower line guard ring 45G may pass through the first lower insulation layer 42 in the first guard ring area GR1 in a vertical direction to contact the first substrate 21. The uppermost ends of the lower line 45, the lower line guard ring 45G, and the first lower insulation layer 42 may form the same or substantially the same plane. The lower line guard ring 45G may include the same material formed simultaneously with the lower line 45.

The second lower insulation layer 52 may cover the first lower insulation layer 42, the lower line 45, and the lower line guard ring 45G. The lower contact plug 56 and the lower contact guard ring 56G may be disposed in the second lower insulation layer 52. The lower contact plug 56 may pass through the second lower insulation layer 52 to contact the lower line 45. The lower contact guard ring 56G may pass through the second lower insulation layer 52 in the first guard ring area GR1 to contact the lower line guard ring 45G.

Upper ends of the lower contact plug 56, the lower contact guard ring 56G, and the second lower insulation layer 52 may form the same or substantially the same plane. The lower contact guard ring 56G may include the same material formed simultaneously with the lower contact plug 56. The lower contact guard ring 56G may have substantially the same thickness as the lower contact plug 56.

The lower insulative bonding layer 62 may cover the second lower insulation layer 52, the lower contact plug 56, and the lower contact guard ring 56G. The lower bonding pad 67 may be disposed in the lower insulative bonding layer 62. The lower bonding pad 67 may pass through the lower insulative bonding layer 62 in the first active area AR1 to contact the lower contact plug 56. The uppermost ends of the lower bonding pad 67 and the lower insulative bonding layer 62 may form the same or substantially the same plane.

The lower insulative bonding layer 62 may be disposed in the first active area AR1 and the first guard ring area GR1. The lower insulative bonding layer 62 may extend from the first active area AR1 to the first guard ring area GR1. The lower insulative bonding layer 62 may fully cover the second lower insulation layer 52 and the lower contact guard ring 56G in the first guard ring area GR1. The lower insulative bonding layer 62 may fully fill on the second lower insulation layer 52 and the lower contact guard ring 56G in the first guard ring area GR1. The lower insulative bonding layer 62 may fully cover the upper surface of the lower contact guard ring 56G. The lower surface of the lower insulative bonding layer 62 may contact the upper surface of the lower contact guard ring 56G. In an embodiment, the lowermost surface of the lower insulative bonding layer 62 may contact the uppermost surface of the lower contact guard ring 56G.

In an embodiment, some or all of the first lower insulation layer 42 and the second lower insulation layer 52 may be referred to as a lower insulation layer. Some or all of the lower line 45 and the lower contact plug 56 may be referred to as a lower line. Some or all of the lower line guard ring 45G and the lower contact guard ring 56G may be referred to as a lower guard ring.

The lower source area 25, the lower drain area 27, the lower channel area 29, the lower gate insulation layer 32, and the lower gate electrode 33 may constitute a lower transistor. The lower bonding pad 67 may be connected to the lower transistor through the lower contact plug 56 and the lower line 45. A plurality of lower transistors may be disposed inside and/or above the first substrate 21. The lower transistor may be a part of a peripheral circuit such as, for example, a page buffer. The first circuit structure CS1 may include a peripheral circuit such as a page buffer and/or a decoder. The lower transistor may include a planar transistor, a recess channel transistor, a vertical transistor, a finFET (fin field effect transistor), a gate all round (GAA) transistor, a multi-bridge channel transistor, or a combination thereof.

The upper insulative bonding layer 72 may be disposed in the second active area AR2 and the second guard ring area GR2. The upper insulative bonding layer 72 may extend from the second active area AR2 to the second guard ring area GR2. The upper insulative bonding layer 72 may be bonded on the lower insulative bonding layer 62. The upper insulative bonding layer 72 may fully cover the lower insulative bonding layer 62 in the first guard ring area GR1. In an embodiment, the upper insulative bonding layer 72 may include the same material as the lower insulative bonding layer 62.

The first upper insulation layer 74 may be disposed on the upper insulative bonding layer 72. The first upper insulation layer 74 may be disposed in the second active area AR2 and the second guard ring area GR2. The first upper insulation layer 74 may extend from the second active area AR2 to the second guard ring area GR2. The first upper insulation layer 74 may fully cover the upper insulative bonding layer 72 in the second guard ring area GR2.

The upper bonding pad 78 may be disposed in the upper insulative bonding layer 72 and the first upper insulation layer 74. The upper bonding pad 78 may pass through the upper insulative bonding layer 72 and the first upper insulation layer 74. The upper bonding pad 78 may be bonded on the lower bonding pad 67. Lowermost ends of the upper bonding pad 78 and the upper insulative bonding layer 72 may form the same or substantially the same plane.

The second upper insulation layer 82 and the third upper insulation layer 84 may be sequentially stacked on the first upper insulation layer 74. The first upper contact plug 89 and the first upper contact guard ring 89G may be disposed in the second upper insulation layer 82 and the third upper insulation layer 84. The first upper contact plug 89 may pass through the second upper insulation layer 82 and the third upper insulation layer 84 to contact the upper bonding pad 78. The first upper contact guard ring 89G may pass through the second upper insulation layer 82 and the third upper insulation layer 84 in the second guard ring area GR2 to contact the first upper insulation layer 74. In an embodiment, the lowermost surface of the first upper contact guard ring 89G may contact the uppermost surface of the first upper insulation layer 74. The first upper insulation layer 74 may fully cover the lower surface of the first upper contact guard ring 89G.

The first upper contact guard ring 89G may include the same material formed simultaneously with the first upper contact plug 89. The first upper contact guard ring 89G may have substantially the same thickness as the first upper contact plug 89. Lowermost ends of the first upper contact plug 89, the first upper contact guard ring 89G, and the second upper insulation layer 82 may form the same or substantially the same plane.

In an embodiment, the lower insulative bonding layer 62 may extend into the first guard ring area GR1 between the lower contact guard ring 56G and the first upper contact guard ring 89G. The upper insulative bonding layer 72 may extend into the second guard ring area GR2 between the lower contact guard ring 56G and the first upper contact guard ring 89G. The first upper insulation layer 74 may extend into the second guard ring area GR2 between the lower contact guard ring 56G and the first upper contact guard ring 89G.

In an embodiment, the lower insulative bonding layer 62 may fully fill the inside of the first guard ring area GR1 between the lower contact guard ring 56G and the first upper contact guard ring 89G. The upper insulative bonding layer 72 and the first upper insulation layer 74 may fully fill the inside of the second guard ring area GR2 between the lower contact guard ring 56G and the first upper contact guard ring 89G. The upper insulative bonding layer 72 and the first upper insulation layer 74 may fully cover the lower surface of the first upper contact guard ring 89G. The first upper insulation layer 74 may fully fill the inside of the second guard ring area GR2 between the first upper contact guard ring 89G and the upper insulative bonding layer 72.

The fourth upper insulation layer 92 may be disposed on the third upper insulation layer 84, the first upper contact plug 89, and the first upper contact guard ring 89G. A bit line 93, a first upper line 93′, and a first upper line guard ring 93G may be disposed in the fourth upper insulation layer 92. The bit line 93 may contact a corresponding one among the first upper contact plugs 89. The first upper line 93′ may contact another corresponding one among the first upper contact plugs 89. The first upper line guard ring 93G may contact the first upper contact guard ring 89G. The bit line 93, the first upper line 93′, and the first upper line guard ring 93G may include the same material formed simultaneously. The bit line 93, the first upper line 93′, and the first upper line guard ring 93G may have substantially the same thickness. Lowermost ends of the fourth upper insulation layer 92, the bit line 93, the first upper line 93′, and the first upper line guard ring 93G may form the same or substantially the same plane.

The fifth upper insulation layer 96 may be disposed on the fourth upper insulation layer 92, the bit line 93, the first upper line 93′, and the first upper line guard ring 93G. The bit contact plug 97, the second upper contact plug 97′, and the second upper contact guard ring 97G may be disposed in the fifth upper insulation layer 96. The bit contact plug 97 may pass through the fifth upper insulation layer 96 to contact the bit line 93. The second upper contact plug 97′ may pass through the fifth upper insulation layer 96 to contact the first upper line 93′. The second upper contact guard ring 97G may pass through the fifth upper insulation layer 96 to contact the first upper line guard ring 93G. The bit contact plug 97, the second upper contact plug 97′, and the second upper contact guard ring 97G may include the same material formed simultaneously. The bit contact plug 97, the second upper contact plug 97′, and the second upper contact guard ring 97G may have substantially the same thickness. Lowermost ends of the fifth upper insulation layer 96, the bit contact plug 97, the second upper contact plug 97′, and the second upper contact guard ring 97G may form the same or substantially the same plane.

The sixth upper insulation layer 102 and the stack structure ST may be disposed on the fifth upper insulation layer 96, the bit contact plug 97, the second upper contact plug 97′, and the second upper contact guard ring 97G. The drain pad 168 of the channel structure 169 may contact the bit contact plug 97. The sixth upper insulation layer 102 may be disposed on the side surface of the stack structure ST. The third upper contact plug 105 and the third upper contact guard ring 105G may be disposed in the sixth upper insulation layer 102. The third upper contact plug 105 may pass through the sixth upper insulation layer 102 to contact the second upper contact plug 97′. The third upper contact guard ring 105G may pass through the sixth upper insulation layer 102 to contact the second upper contact guard ring 97G. The third upper contact guard ring 105G may include the same material formed simultaneously with the third upper contact plug 105.

The common source line 118 may be disposed on the stack structure ST. The common source line 118 may contact the channel pattern 164 of the channel structure 169. The seventh upper insulation layer 122 may be disposed on the sixth upper insulation layer 102, the stack structure ST, the third upper contact plug 105, the third upper contact guard ring 105G, and the common source line 118. The fourth upper contact plug 125 and the fourth upper contact guard ring 125G may be disposed in the seventh upper insulation layer 122. The fourth upper contact plug 125 may pass through the seventh upper insulation layer 122 to contact the common source line 118 or the third upper contact plug 105. The fourth upper contact guard ring 125G may pass through the seventh upper insulation layer 122 to contact the third upper contact guard ring 105G. The fourth upper contact guard ring 125G may include the same material formed simultaneously with the fourth upper contact plug 125.

The second upper line 129 and the second upper line guard ring 129G may be disposed on the seventh upper insulation layer 122, the fourth upper contact plug 125, and the fourth upper contact guard ring 125G. The second upper line 129 may contact the fourth upper contact plug 125. The second upper line guard ring 129G may contact the fourth upper contact guard ring 125G. The second upper line guard ring 129G may include the same material formed simultaneously with the second upper line 129. The second upper line guard ring 129G may have substantially the same thickness as the second upper line 129.

In an embodiment, some or all of the second upper insulation layer 82, the third upper insulation layer 84, the fourth upper insulation layer 92, the fifth upper insulation layer 96, the sixth upper insulation layer 102, and the seventh upper insulation layer 122 may be referred to as an upper insulation layer. Some or all of the first upper contact plug 89, the bit line 93, the first upper line 93′, the bit contact plug 97, the second upper contact plug 97′, the third upper contact plug 105, the fourth upper contact plug 125, and the second upper line 129 may be referred to as an upper line. Some or all of the first upper contact guard ring 89G, the first upper line guard ring 93G, the second upper contact guard ring 97G, the third upper contact guard ring 105G, the fourth upper contact guard ring 125G, and the second upper line guard ring 129G may be referred to as an upper guard ring.

The channel structure 169 may be connected to the lower drain area 27 through the bit contact plug 97, the bit line 93, the first upper contact plug 89, the upper bonding pad 78, the lower bonding pad 67, the lower contact plug 56, and the lower line 45. The stack structure ST, the plurality of channel structures 169, and the common source line 118 may constitute the cell array of the flash memory. The second circuit structure CS2 may include a non-volatile memory such as a flash memory.

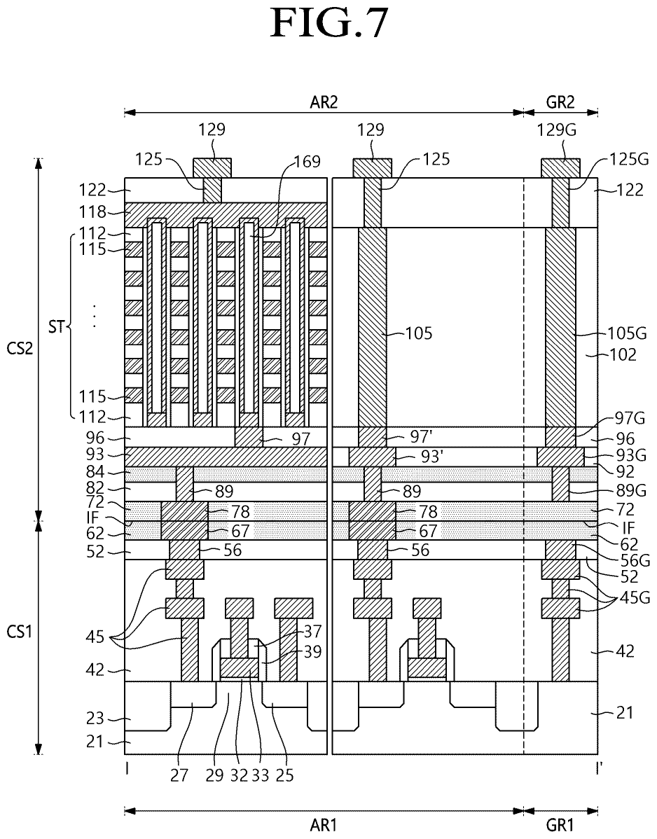

FIG. 7 is a cross-sectional view illustrating a semiconductor device according to an embodiment of the present disclosure.

Referring to FIG. 7, a semiconductor device according to an embodiment of the present disclosure may include a first circuit structure CS1 and a second circuit structure CS2 bonded on the first circuit structure CS1. The first circuit structure CS1 may include a first active area AR1 and a first guard ring area GR1. The second circuit structure CS2 may include a second active area AR2 and a second guard ring area GR2.

The first circuit structure CS1 may include a first substrate 21, an element isolation layer 23, a lower source area 25, a lower drain area 27, a lower channel area 29, a lower gate insulation layer 32, a lower gate electrode 33, a gate capping layer 37, a gate spacer 39, a first lower insulation layer 42, a lower line 45, a lower line guard ring 45G, a second lower insulation layer 52, a lower contact plug 56, a lower contact guard ring 56G, a lower insulative bonding layer 62, and a lower bonding pad 67.

The second circuit structure CS2 may include an upper insulative bonding layer 72, an upper bonding pad 78, a second upper insulation layer 82, a third upper insulation layer 84, a first upper contact plug 89, a first upper contact guard ring 89G, a fourth upper insulation layer 92, a bit line 93, a first upper line 93′, a first upper line guard ring 93G, a fifth upper insulation layer 96, a bit contact plug 97, a second upper contact plug 97′, a second upper contact guard ring 97G, a sixth upper insulation layer 102, a stack structure ST, a third upper contact plug 105, a third upper contact guard ring 105G, a common source line 118, a seventh upper insulation layer 122, a fourth upper contact plug 125, a fourth upper contact guard ring 125G, a second upper line 129, a second upper line guard ring 129G, and a plurality of channel structures 169. The stack structure ST may include a plurality of molding layers 112 and a plurality of horizontal electrodes 115 that are alternately stacked. In an embodiment, the first upper insulation layer (74 of FIG. 1) may be omitted.

The upper insulative bonding layer 72 may fully fill the inside of the second guard ring area GR2 between the lower contact guard ring 56G and the first upper contact guard ring 89G. The upper insulative bonding layer 72 may fully cover the lower surface of the first upper contact guard ring 89G. In an embodiment, the lowermost surface of the first upper contact guard ring 89G may contact the uppermost surface of the upper insulative bonding layer 72.

According to an embodiment of the present disclosure, the lower bonding pad 67 may be disposed in the lower insulative bonding layer 62 in the first active area AR1, and the lower insulative bonding layer 62 may extend into the first guard ring area GR1. The lower insulative bonding layer 62 may fully cover the first guard ring area GR1. The upper bonding pad 78 may be disposed in the upper insulative bonding layer 72 in the second active area AR2, and the upper insulative bonding layer 72 may extend into the second guard ring area GR2. The upper insulative bonding layer 72 may fully cover the second guard ring area GR2. The upper insulative bonding layer 72 in the second guard ring area GR2 may be bonded on the lower insulative bonding layer 62 in the first guard ring area GR1. The coupling strength between the first and the second circuit structures CS1 and CS2 may be increased.

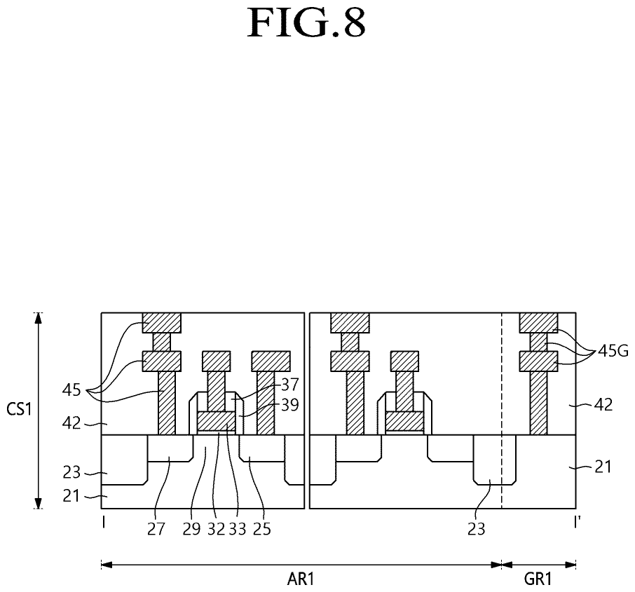

FIGS. 8 to 20 are cross-sectional views illustrating a method for forming a semiconductor device according to embodiments of the present disclosure. In an embodiment, FIGS. 8 to 20 may be cross-sectional views taken along the cutting line I-I′ of FIGS. 2 to 5.

Referring to FIG. 8, an element isolation layer 23, a lower source area 25, a lower drain area 27, a lower channel area 29, a lower gate insulation layer 32, a lower gate electrode 33, a gate capping layer 37, a gate spacer 39, a first lower insulation layer 42, a lower line 45, and a lower line guard ring 45G may be formed on the first substrate 21.

The first substrate 21 may extend from the first active area AR1 to the first guard ring area GR1. The first substrate 21 may include a semiconductor substrate such as a silicon wafer or a silicon on insulator (SOI) wafer. The first substrate 21 may include a group III-V semiconductor substrate, e.g., a compound semiconductor substrate such as Gallium Arsenide (GaAs). The first substrate 21 may include mono-crystalline silicon, polysilicon, amorphous silicon, mono-crystalline silicon germanium, poly-crystalline silicon germanium, carbon-doped silicon, or a combination thereof.

The element isolation layer 23 may be formed using a trench isolation technique from the upper surface of the first substrate 21 to a predetermined depth. The lower source area 25 and the lower drain area 27 may be formed using an ion implantation technique from the upper surface of the first substrate 21 to a predetermined depth. The lower channel area 29 may be limited between the lower source area 25 and the lower drain area 27 in the first substrate 21. The lower source area 25 and the lower drain area 27 may include impurities of different conductivity-type from those of the lower channel area 29.

In an embodiment, the lower channel area 29 may include a semiconductor layer such as mono-crystalline silicon having P-type impurities. The lower source area 25 and the lower drain area 27 may include a semiconductor layer having N-type impurities. In an embodiment, the lower channel area 29 may include a semiconductor layer having N-type impurities, while the lower source area 25 and the lower drain area 27 may include a semiconductor layer having P-type impurities.

The lower gate insulation layer 32 may be formed on the lower channel area 29. The lower gate electrode 33 may be formed on the lower gate insulation layer 32. The lower gate electrode 33 may be aligned on the lower channel area 29. The lower gate electrode 33 may overlap with the lower channel area 29. The gate capping layer 37 may be formed on the lower gate electrode 33. The gate capping layer 37 may cover the lower gate electrode 33. The gate spacer 39 may be formed on side surfaces of the gate capping layer 37 and the lower gate electrode 33. The first lower insulation layer 42 may cover the first substrate 21, the element isolation layer 23, the lower source area 25, the lower drain area 27, the lower channel area 29, the lower gate insulation layer 32, the lower gate electrode 33, the gate capping layer 37, and the gate spacer 39.

The lower line 45 and the lower line guard ring 45G may be formed in the first lower insulation layer 42. The lower line 45 and the lower line guard ring 45G may include a plurality of horizontal lines and a plurality of vertical lines. The lower line guard ring 45G may include the same material as the lower line 45 and may be formed simultaneously with the lower line 45. The lower line 45 may pass through the first lower insulation layer 42 to contact the lower source area 25 or the lower drain area 27. At least one of the lower line 45 may pass through the first lower insulation layer 42 and the gate capping layer 37 to contact the lower gate electrode 33. The lower line guard ring 45G may pass through the first lower insulation layer 42 to contact the first substrate 21.

The element isolation layer 23, the lower gate insulation layer 32, the gate capping layer 37, the gate spacer 39, and the first lower insulation layer 42 may include at least two selected from the group consisting of silicon (Si), oxygen (O), nitrogen (N), carbon (C), boron (B), phosphorus (P), and hydrogen (H). In an embodiment, the lower gate insulation layer 32 may include silicon oxide, silicon nitride, silicon oxynitride, high-K dielectric, or a combination thereof. The element isolation layer 23, the gate capping layer 37, the gate spacer 39, and the first lower insulation layer 42 may include silicon oxide, silicon nitride, silicon oxynitride, low-K dielectric, high-K dielectric, or a combination thereof. The lower gate electrode 33, the lower line 45, and the lower line guard ring 45G may include metal, metal nitride, metal oxide, metal silicide, polysilicon, conductive carbon, or a combination thereof.

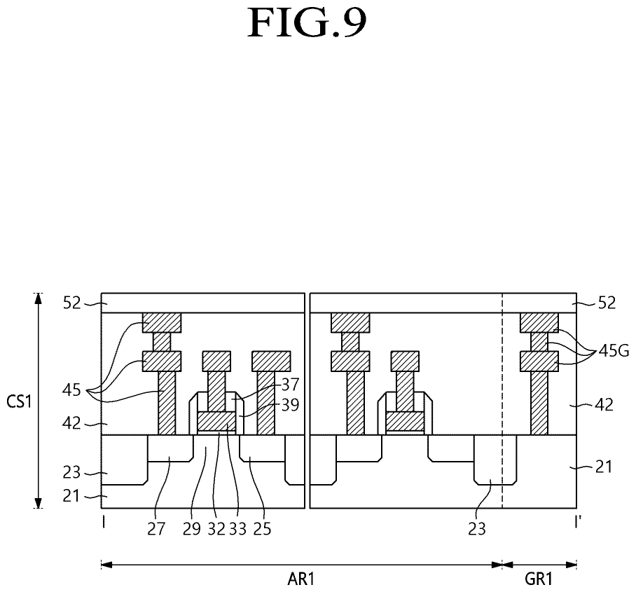

Referring to FIG. 9, a second lower insulation layer 52 may be formed on the first lower insulation layer 42. The second lower insulation layer 52 may cover the lower line 45 and the lower line guard ring 45G. The second lower insulation layer 52 may include at least two selected from the group consisting of silicon (Si), oxygen (O), nitrogen (N), carbon (C), boron (B), phosphorus (P), and hydrogen (H). In an embodiment, the second lower insulation layer 52 may include silicon oxide, silicon nitride, silicon oxynitride, low-K dielectric, high-K dielectric, or a combination thereof.

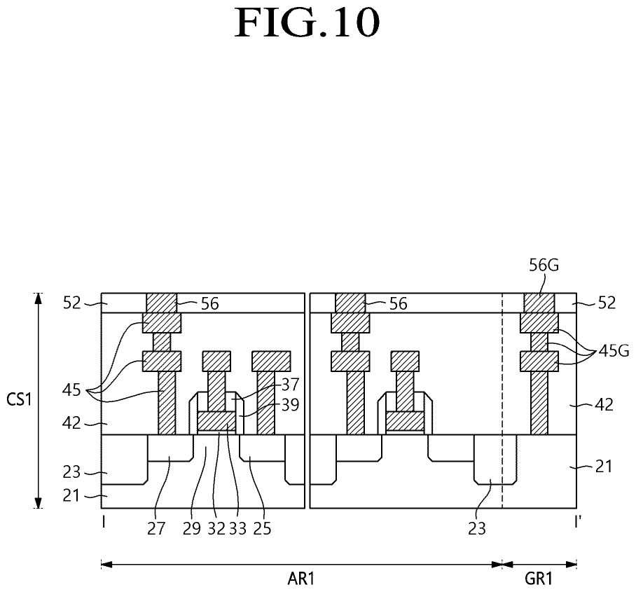

Referring to FIG. 10, a lower contact plug 56 and a lower contact guard ring 56G may be formed in the second lower insulation layer 52. The lower contact plug 56 may pass through the second lower insulation layer 52 to contact the lower line 45. The lower contact guard ring 56G may pass through the second lower insulation layer 52 to contact the lower line guard ring 45G. The lower contact guard ring 56G may include the same material as the lower contact plug 56 and may be formed simultaneously with the lower contact plug 56. The lower contact plug 56 and the lower contact guard ring 56G may include metal, metal nitride, metal oxide, metal silicide, polysilicon, conductive carbon, or a combination thereof.

Formation of the lower contact plug 56 and the lower contact guard ring 56G may include a thin film forming process and a planarization process. In an embodiment, upper surfaces of the second lower insulation layer 52, the lower contact plug 56, and the lower contact guard ring 56G may be planarized using a chemical mechanical polishing (CMP) process. Upper surfaces of the second lower insulation layer 52, the lower contact plug 56, and the lower contact guard ring 56G may form the same or substantially the same plane.

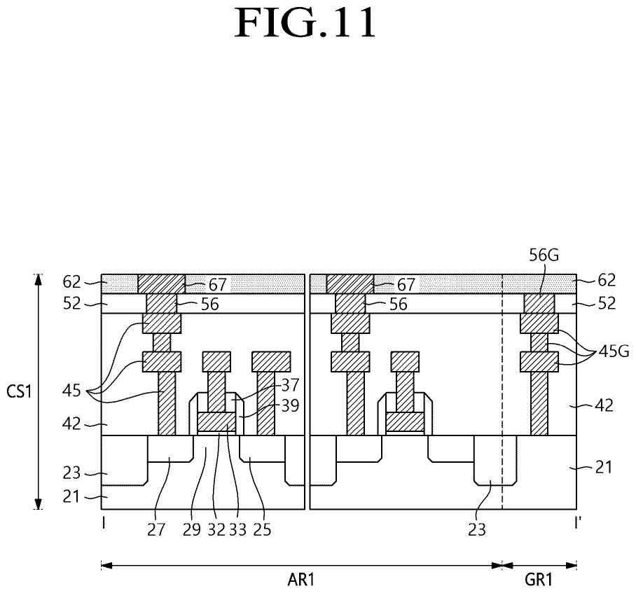

Referring to FIG. 11, a lower insulative bonding layer 62 may be formed on the second lower insulation layer 52, the lower contact plug 56, and the lower contact guard ring 56G. A lower bonding pad 67 may be formed in the lower insulative bonding layer 62. The lower bonding pad 67 may pass through the lower insulative bonding layer 62 in the first active area AR1 to contact the lower contact plug 56.

In an embodiment, the upper surfaces of the lower insulative bonding layer 62 and the lower bonding pad 67 may be planarized using a chemical mechanical polishing (CMP) process. Upper surfaces of the lower insulative bonding layer 62 and the lower bonding pad 67 may form the same or substantially the same plane. The lower insulative bonding layer 62 may fully cover the upper surface of the lower contact guard ring 56G. The lower insulative bonding layer 62 may fully cover upper surfaces of the second lower insulation layer 52 and the lower contact guard ring 56G in the first guard ring area GR1.

The lower insulative bonding layer 62 may include at least two selected from the group consisting of silicon (Si), oxygen (O), nitrogen (N), carbon (C), boron (B), phosphorus (P), and hydrogen (H). In an embodiment, the lower insulative bonding layer 62 may include Silicon Carbon Nitride (SiCN), Silicon Oxycarbide Nitride (SiOCN), Silicon Hydroxyl Nitride (SiOHN), Silicon Carbon Hydrogen Nitride (SiCHN), Silicon Oxycarbide Hydrogen Nitride (SiOCHN), or a combination thereof. The lower bonding pad 67 may include metal, metal nitride, metal oxide, metal silicide, polysilicon, conductive carbon, or a combination thereof. In an embodiment, the lower bonding pad 67 may include a copper layer formed using an electroplating method.

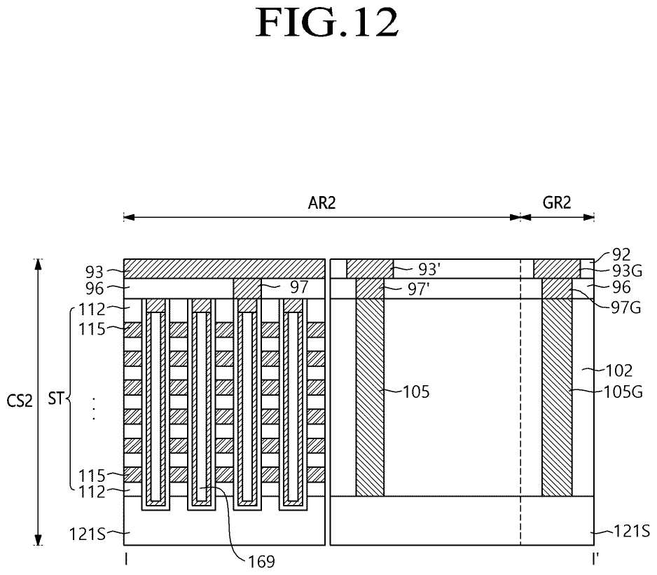

Referring to FIG. 12, a stack structure ST, a sixth upper insulation layer 102, a third upper contact guard ring 105, a third upper contact guard ring 105G, a plurality of channel structures 169, a fifth upper insulation layer 96, a bit contact plug 97, a second upper contact plug 97′, a second upper contact guard ring 97G, a fourth upper insulation layer 92, a bit line 93, a first upper line 93′, and a first upper line guard ring 93G may be formed over the second substrate 121S. The second substrate 121S may include a semiconductor substrate the same or similar to the first substrate 21. The second substrate 121S may extend from the second active area AR2 to the second guard ring area GR2.

The stack structure ST, the plurality of channel structures 169, and the sixth upper insulation layer 102 may be formed on the second substrate 121S. The stack structure ST may include a plurality of molding layers 112 and a plurality of horizontal electrodes 115 that are alternately stacked. Each of a plurality of channel structures 169 may pass through the stack structure ST in a vertical direction and extend into the second substrate 121S. Each of the plurality of channel structures 169 may include an information storage pattern 157, a channel pattern 164, a core layer 166, and a drain pad 168, as shown in FIG. 6. The information storage pattern 157 may include a tunnel layer 151, a charge trap layer 153, and a blocking layer 155.

The plurality of molding layers 112 may include at least two selected from the group consisting of silicon (Si), oxygen (O), nitrogen (N), carbon (C), boron (B), phosphorus (P), and hydrogen (H). In an embodiment, the plurality of molding layers 112 may include silicon oxide. The plurality of horizontal electrodes 115 may include metal, metal nitride, metal oxide, metal silicide, polysilicon, conductive carbon, or a combination thereof. In an embodiment, the plurality of horizontal electrodes 115 may include tungsten (W), tungsten nitride (WN), titanium (Ti), titanium nitride (TiN), tantalum (Ta), tantalum nitride (TaN), or a combination thereof.

The channel pattern 164 may include a semiconductor layer such as a polysilicon layer. The core layer 166 may include an insulation layer, a conductive layer, or a combination thereof. In an embodiment, the core layer 166 may include at least two selected from the group consisting of silicon (Si), oxygen (O), nitrogen (N), carbon (C), boron (B), phosphorus (P), and hydrogen (H). The core layer 166 may include silicon oxide, silicon nitride, silicon oxynitride, low-K dielectric, high-K dielectric, or a combination thereof. The drain pad 168 may include a semiconductor layer such as a polysilicon layer.

The sixth upper insulation layer 102 may cover a side surface of the stack structure ST and extend to the second guard ring area GR2. The third upper contact plug 105 and the third upper contact guard ring 105G may pass through the sixth upper insulation layer 102 in a vertical direction to contact the second substrate 121S. The third upper contact guard ring 105G may include the same material formed simultaneously with the third upper contact plug 105.

The fifth upper insulation layer 96 may be formed on the stack structure ST, the plurality of channel structures 169, the sixth upper insulation layer 102, the third upper contact plug 105, and the third upper contact guard ring 105G. The bit contact plug 97, the second upper contact plug 97′, and the second upper contact guard ring 97G may be formed in the fifth upper insulation layer 96. The bit contact plug 97, the second upper contact plug 97′, and the second upper contact guard ring 97G may include the same material and may be formed simultaneously. The bit contact plug 97 may pass through the fifth upper insulation layer 96 to be connected to a corresponding one among the plurality of channel structures 169. The second upper contact plug 97′ may pass through the fifth upper insulation layer 96 to contact the third upper contact plug 105. The second upper contact guard ring 97G may pass through the fifth upper insulation layer 96 to contact the third upper contact guard ring 105G.

The fourth upper insulation layer 92 may be formed on the fifth upper insulation layer 96, the bit contact plug 97, the second upper contact plug 97′, and the second upper contact guard ring 97G. The bit line 93, the first upper line 93′, and the first upper line guard ring 93G may be formed in the fourth upper insulation layer 92. The bit line 93, the first upper line 93′, and the first upper line guard ring 93G may include the same material formed simultaneously. The bit line 93 may contact the bit contact plug 97. The first upper line 93′ may contact the second upper contact plug 97′. The first upper line guard ring 93G may contact the second upper contact guard ring 97G.

The fourth upper insulation layer 92, the fifth upper insulation layer 96, and the sixth upper insulation layer 102 may include at least two selected from the group consisting of silicon (Si), oxygen (O), nitrogen (N), carbon (C), boron (B), phosphorus (P), and hydrogen (H). In an embodiment, the fourth upper insulation layer 92, the fifth upper insulation layer 96, and the sixth upper insulation layer 102 may include silicon oxide, silicon nitride, silicon oxynitride, low-K dielectric, high-K dielectric, or a combination thereof.

The bit line 93, the first upper line 93′, the first upper line guard ring 93G, the bit contact plug 97, the second upper contact plug 97′, the second upper contact guard ring 97G, the third upper contact plug 105, and the third upper contact guard ring 105G may include metal, metal nitride, metal oxide, metal silicide, polysilicon, conductive carbon, or a combination thereof. In an embodiment, the bit line 93, the first upper line 93′, the first upper line guard ring 93G, the bit contact plug 97, the second upper contact plug 97′, the second upper contact guard ring 97G, the third upper contact plug 105, and the third upper contact guard ring 105G may include tungsten (W), tungsten nitride (WN), titanium nitride (Ti), titanium nitride (TiN), tantalum (Ta), tantalum nitride (TaN), or a combination thereof.

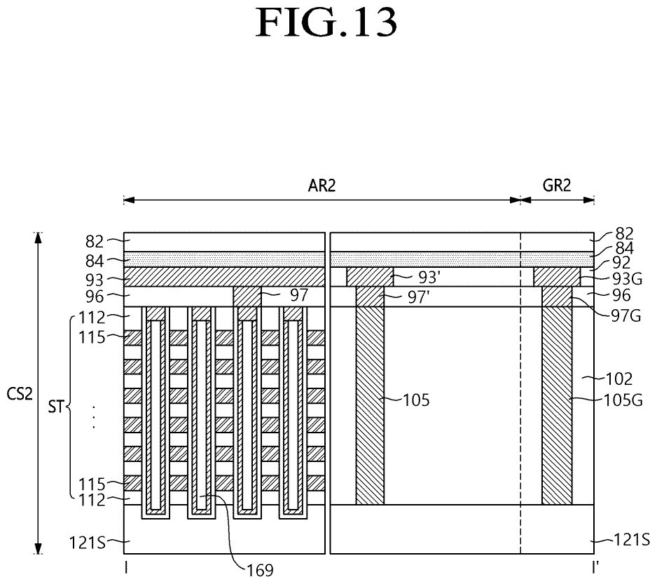

Referring to FIG. 13, the third upper insulation layer 84 and the second upper insulation layer 82 may be sequentially stacked on the fourth upper insulation layer 92, the bit line 93, the first upper line 93′, and the first upper line guard ring 93G. The third upper insulation layer 84 and the second upper insulation layer 82 may include at least two selected from the group consisting of silicon (Si), oxygen (O), nitrogen (N), carbon (C), boron (B), phosphorus (P), and hydrogen (H). In an embodiment, the third upper insulation layer 84 may include SiN, SiCN, SiOCN, SiOHN, SiCHN, SiOCHN, or a combination thereof. The second upper insulation layer 82 may include SiO, SiOH, SiCH, SiCOH, or a combination thereof.

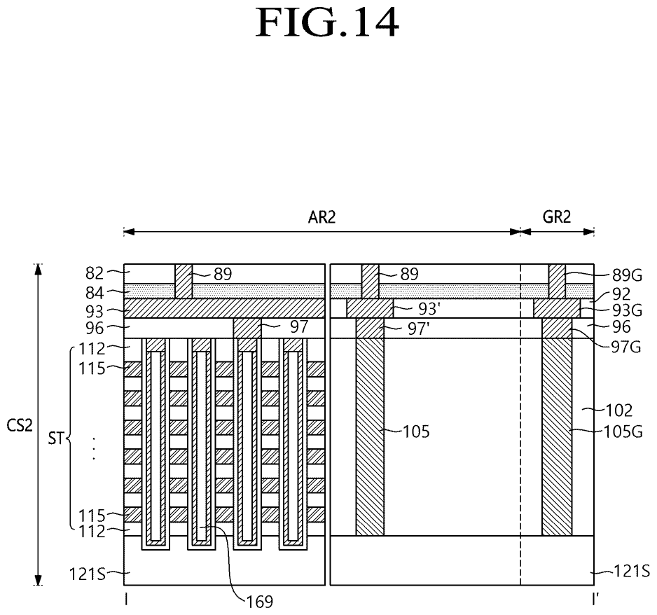

Referring to FIG. 14, a first upper contact plug 89 and a first upper contact guard ring 89G may be formed in the third upper insulation layer 84 and the second upper insulation layer 82. The first upper contact plug 89 may pass through the third upper insulation layer 84 and the second upper insulation layer 82 in a vertical direction to contact the bit line 93 or the first upper line 93′. The first upper contact guard ring 89G may pass through the third upper insulation layer 84 and the second upper insulation layer 82 in a vertical direction to contact the first upper line guard ring 93G. Upper surfaces of the second upper insulation layer 82, the first upper contact plug 89, and the first upper contact guard ring 89G may be planarized using a chemical mechanical polishing (CMP) process. Upper surfaces of the second upper insulation layer 82, the first upper contact plug 89, and the first upper contact guard ring 89G may form the same or substantially the same plane.

The first upper contact guard ring 89G may include the same material formed simultaneously with the first upper contact plug 89. The first upper contact plug 89 and the first upper contact guard ring 89G may include metal, metal nitride, metal oxide, metal silicide, polysilicon, conductive carbon, or a combination thereof. In an embodiment, the first upper contact plug 89 and the first upper contact guard ring 89G may include copper (Cu), tungsten (W), tungsten nitride (WN), titanium (Ti), titanium nitride (TiN), tantalum (Ta), tantalum nitride (TaN), or a combination thereof.

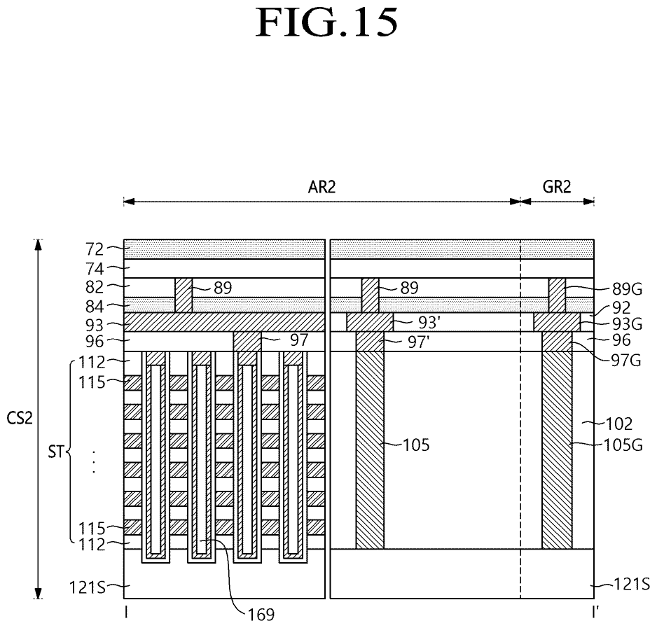

Referring to FIG. 15, the first upper insulation layer 74 and the upper insulative bonding layer 72 may be sequentially stacked on the second upper insulation layer 82, the first upper contact plug 89, and the first upper contact guard ring 89G.

The first upper insulation layer 74 may include a material different from that of the upper insulative bonding layer 72. The first upper insulation layer 74 may include at least two selected from the group consisting of silicon (Si), oxygen (O), nitrogen (N), carbon (C), boron (B), phosphorus (P), and hydrogen (H). In an embodiment, the first upper insulation layer 74 may include SiN, SiO, SiOH, SiCH, SiCOH, SiCN, SiOCN, SiOHN, SiCHN, SiOCHN, or a combination thereof.

The upper insulative bonding layer 72 may include at least two selected from the group consisting of silicon (Si), oxygen (O), nitrogen (N), carbon (C), boron (B), phosphorus (P), and hydrogen (H). In an embodiment, the upper insulative bonding layer 72 may include SiCN, SiOCN, SiOHN, SiCHN, SiOCHN, or a combination thereof. The upper insulative bonding layer 72 may include the same material as the lower insulative bonding layer 62.

The first upper insulation layer 74 and the upper insulative bonding layer 72 may fully cover the upper surface of the first upper contact guard ring 89G. The first upper insulation layer 74 and the upper insulative bonding layer 72 may fully cover upper surfaces of the second upper insulation layer 82 and the first upper contact guard ring 89G in the second guard ring area GR2. The first upper insulation layer 74 may contact the uppermost end of the first upper contact guard ring 89G. The first upper insulation layer 74 may be omitted.

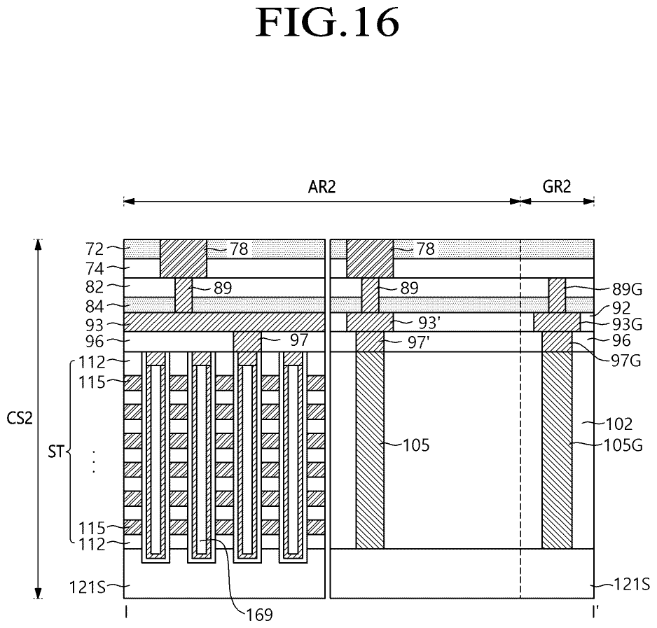

Referring to FIG. 16, an upper bonding pad 78 may be formed in the first upper insulation layer 74 and the upper insulative bonding layer 72. The upper bonding pad 78 may pass through the upper insulative bonding layer 72 and the first upper insulation layer 74 in a vertical direction to contact the first upper contact plug 89. The upper surfaces of the upper insulative bonding layer 72 and the upper bonding pad 78 may be planarized using a chemical mechanical polishing (CMP) process. Upper surfaces of the upper insulative bonding layer 72 and the upper bonding pad 78 may form the same or substantially the same plane.

The upper bonding pad 78 may include metal, metal nitride, metal oxide, metal silicide, polysilicon, conductive carbon, or a combination thereof. In an embodiment, the upper bonding pad 78 may include a copper layer formed using an electroplating method. The upper bonding pad 78 may include the same material as the lower bonding pad 67.

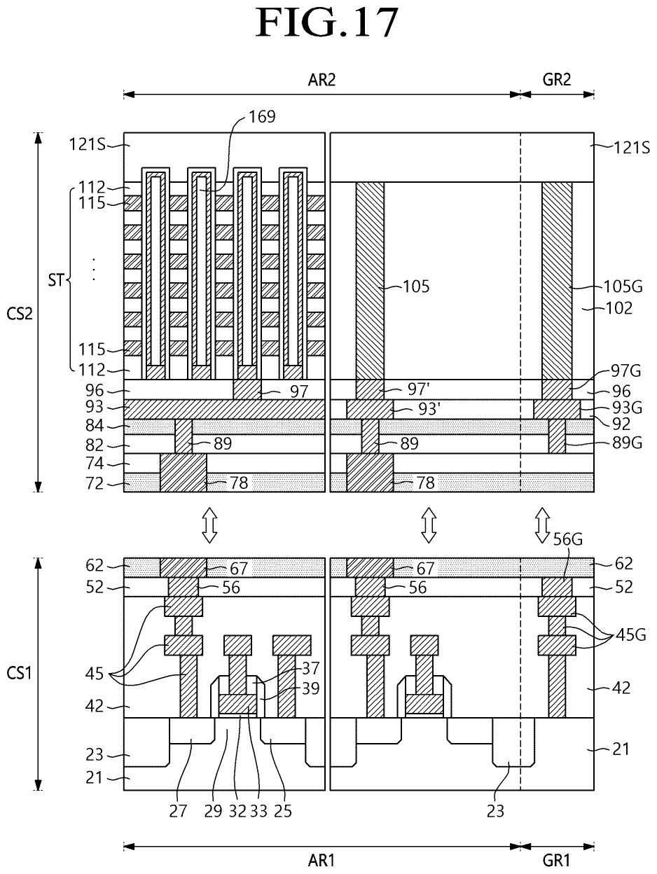

Referring to FIG. 17, the second circuit structure CS2 may be bonded on the first circuit structure CS1. The upper insulative bonding layer 72 and the upper bonding pad 78 may be bonded to the lower insulative bonding layer 62 and the lower bonding pad 67 to face each other.

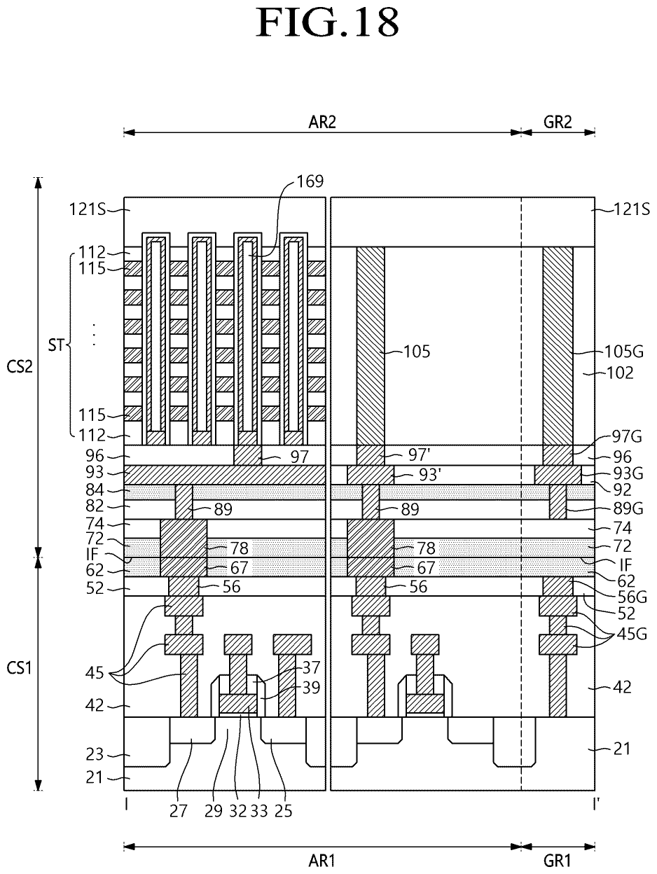

Referring to FIG. 18, an upper insulative bonding layer 72 may be bonded on the lower insulative bonding layer 62, and an upper bonding pad 78 may be bonded on the lower bonding pad 67. An interface IF may be formed between the lower insulative bonding layer 62 and the upper insulative bonding layer 72 and between the lower bonding pad 67 and the upper bonding pad 78. The lower insulative bonding layer 62, the upper insulative bonding layer 72, and the first upper insulation layer 74 may fully fill the first guard ring area GR1 and the second guard ring area GR2 between the lower contact guard ring 56G and the first upper contact guard ring 89G. The coupling strength between the first circuit structure CS1 and the second circuit structure CS2 may be increased.

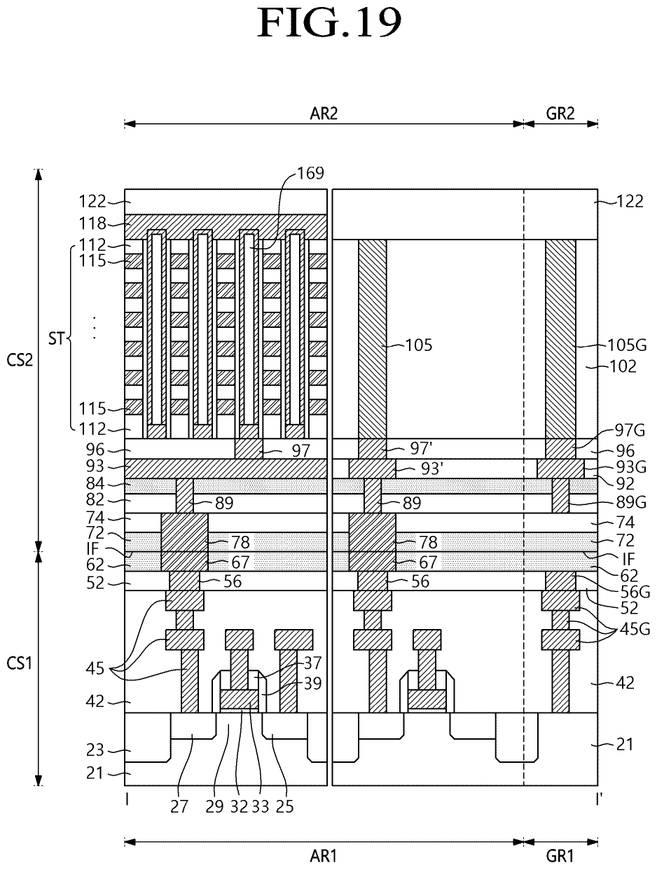

Referring to FIG. 19, the stack structure ST, the sixth upper insulation layer 102, the third upper contact plug 105, and the third upper contact guard ring 105G may be exposed by removing the second substrate 121S. The channel pattern (164 of FIG. 6) may be exposed by partially removing the information storage pattern (157 of FIG. 6). A common source line 118 may be formed on the stack structure ST. The common source line 118 may contact the channel pattern (164 of FIG. 6). The common source line 118 may include metal, metal nitride, metal oxide, metal silicide, polysilicon, conductive carbon, or a combination thereof. In an embodiment, the common source line 118 may include a semiconductor layer such as a polysilicon layer.

A seventh upper insulation layer 122 may be formed on the common source line 118, the sixth upper insulation layer 102, the third upper contact plug 105, and the third upper contact guard ring 105G. The seventh upper insulation layer 122 may include at least two selected from the group consisting of silicon (Si), oxygen (O), nitrogen (N), carbon (C), boron (B), phosphorus (P), and hydrogen (H). In an embodiment, the seventh upper insulation layer 122 may include silicon oxide, silicon nitride, silicon oxynitride, low-K dielectric, high-K dielectric, or a combination thereof.

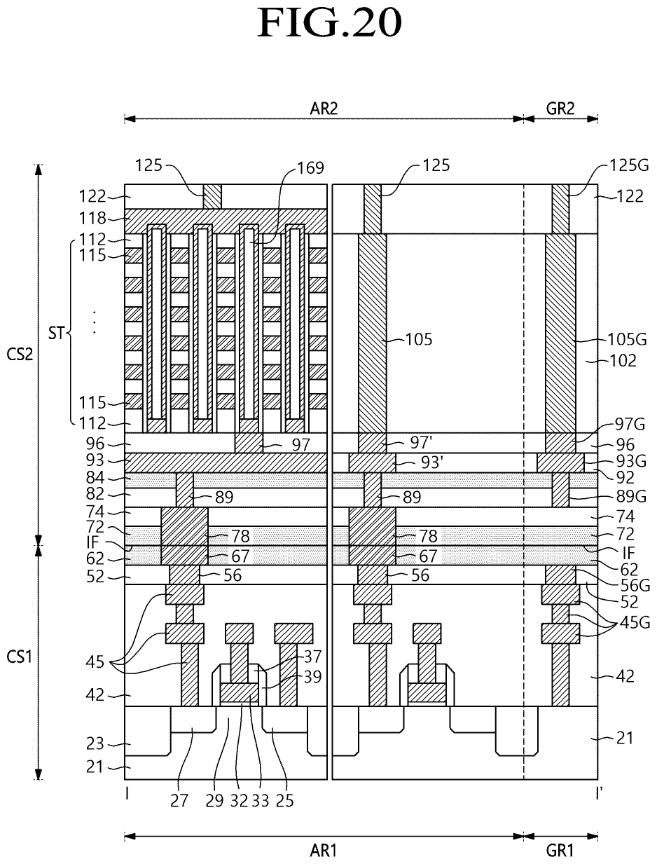

Referring to FIG. 20, a fourth upper contact plug 125 and a fourth upper contact guard ring 125G may be formed in the seventh upper insulation layer 122. The fourth upper contact guard ring 125G may include the same material formed simultaneously with the fourth upper contact plug 125. One selected from the fourth upper contact plugs 125 may contact the common source line 118. Another one selected from the fourth upper contact plugs 125 may contact the third upper contact plug 105. The fourth upper contact guard ring 125G may contact the third upper contact guard ring 105G.

The fourth upper contact plug 125 and the fourth upper contact guard ring 125G may include metal, metal nitride, metal oxide, metal silicide, polysilicon, conductive carbon, or a combination thereof. In an embodiment, the fourth upper contact plug 125 and the fourth upper contact guard ring 125G may include copper (Cu), tungsten (W), tungsten nitride (WN), titanium (Ti), titanium nitride (TiN), tantalum (Ta), tantalum nitride (TaN), or a combination thereof.

Referring back to FIG. 1, a second upper line 129 and a second upper line guard ring 129G may be formed on the seventh upper insulation layer 122. The second upper line guard ring 129G may include the same material formed simultaneously with the second upper line 129. The second upper line 129 may contact the fourth upper contact plug 125. The second upper line guard ring 129G may contact the fourth upper contact guard ring 125G. The second upper line 129 and the second upper line guard ring 129G may include metal, metal nitride, metal oxide, metal silicide, polysilicon, conductive carbon, or a combination thereof. In an embodiment, the second upper line 129 and the second upper line guard ring 129G may include copper (Cu), tungsten (W), tungsten nitride (WN), titanium (Ti), titanium nitride (TiN), tantalum (Ta), tantalum nitride (TaN), or a combination thereof.

The above-described embodiments are merely illustrative, and it will be appreciated by one of ordinary skill in the art that various changes may be made thereto without departing from the scope of the present disclosure. Accordingly, the embodiments set forth herein are provided for illustrative purposes, and should not limit the scope of the present disclosure. Furthermore, the embodiments may be combined to form additional embodiments.

What is claimed is:

1. A semiconductor device comprising:
a first circuit structure having a first active area and a first guard ring area; and
a second circuit structure bonded on the first circuit structure, the second circuit structure having a second active area and a second guard ring area,
wherein the first circuit structure includes:
a lower insulation layer;
a lower line disposed in the lower insulation layer in the first active area;
a lower guard ring disposed in the lower insulation layer in the first guard ring area;
a lower insulative bonding layer disposed on the lower insulation layer, the lower insulative bonding layer extending in both the first active area and the first guard ring area, and
a lower bonding pad disposed in the lower insulative bonding layer in the first active area, the lower bonding pad being connected to the lower line, wherein the second circuit structure includes:
an upper insulative bonding layer disposed in the second active area and the second guard ring area, the upper insulative bonding layer being bonded on the lower insulative bonding layer;
an upper bonding pad disposed in the upper insulative bonding layer in the second active area, the upper bonding pad being bonded on the lower bonding pad;
an upper insulation layer on the upper insulative bonding layer;
an upper line disposed in the upper insulation layer in the second active area, the upper line being connected to the upper bonding pad; and
an upper guard ring disposed in the upper insulation layer in the second guard ring area,
wherein the lower insulative bonding layer is disposed in the first guard ring area between the lower guard ring and the upper guard ring, and
wherein the upper insulative bonding layer is disposed in the second guard ring area between the lower guard ring and the upper guard ring.

2. The semiconductor device of claim 1, wherein the lower insulative bonding layer fully fills the first guard ring area between the lower guard ring and the upper guard ring, and
wherein the upper insulative bonding layer fully fills the second guard ring area between the lower guard ring and the upper guard ring.

3. The semiconductor device of claim 1, wherein a lowermost surface of the lower insulative bonding layer contacts an uppermost surface of the lower guard ring, and an uppermost surface of the upper insulative bonding layer contacts a lowermost surface of the upper guard ring.

4. The semiconductor device of claim 1, wherein the lower insulative bonding layer fully covers an upper surface of the lower guard ring, and the upper insulative bonding layer fully covers a lower surface of the upper guard ring.

5. The semiconductor device of claim 1, wherein an uppermost surface of the lower guard ring forms substantially the same plane as an uppermost surface of the lower line.

6. The semiconductor device of claim 1, wherein a lowermost surface of the upper guard ring forms substantially the same plane as a lowermost surface of the upper line.

7. The semiconductor device of claim 1, wherein the second circuit structure further includes a first upper insulation layer disposed between the upper insulative bonding layer and the upper insulation layer and having a material different from the upper insulative bonding layer, and
wherein the upper insulative bonding layer includes SiCN, SiOCN, SiOHN, SiCHN, SiOCHN, or a combination thereof.

8. The semiconductor device of claim 7, wherein the first upper insulation layer fully fills the second guard ring area between the upper guard ring and the upper insulative bonding layer.

9. The semiconductor device of claim 7, wherein the first upper insulation layer fully covers a lower surface of the upper guard ring.

10. The semiconductor device of claim 7, wherein the upper bonding pad penetrates the upper insulative bonding layer and the first upper insulation layer to contact the upper line.

11. The semiconductor device of claim 1, wherein the second circuit structure includes:
a stack structure in the upper insulation layer;
a channel structure penetrating the stack structure; and
a common source line disposed on the stack structure and connected to the channel structure, and
wherein the channel structure is connected to the upper bonding pad through the upper line.

12. The semiconductor device of claim 11, wherein the upper insulation layer includes a second upper insulation layer disposed between the upper insulative bonding layer and the stack structure and extending into the second guard ring area,
wherein the upper line includes a bit line disposed in the second upper insulation layer and connected to the channel structure and the upper bonding pad, and
wherein the upper guard ring includes an upper line guard ring in the second upper insulation layer.

13. The semiconductor device of claim 12, wherein a lowermost end of the upper line guard ring forms substantially the same plane as a lowermost end of the bit line.

14. The semiconductor device of claim 12, wherein the upper insulation layer includes a third upper insulation layer disposed between the upper insulative bonding layer and the second upper insulation layer and extends into the second guard ring area,
wherein the upper line further includes an upper contact plug disposed in the third upper insulation layer and contacts the bit line and the upper bonding pad, and
wherein the upper guard ring further includes an upper contact guard ring disposed in the third upper insulation layer and contacts the upper line guard ring.

15. The semiconductor device of claim 14, wherein a lower surface of the upper contact guard ring forms substantially the same plane as a lower surface of the upper contact plug.

16. The semiconductor device of claim 1, wherein the first circuit structure further includes:
a substrate; and
a lower transistor on the substrate,
wherein the lower insulation layer covers the substrate and the lower transistor, and
wherein the lower transistor is connected to the lower bonding pad through the lower line.

17. A semiconductor device comprising:
a first circuit structure having a first active area and a first guard ring area; and
a second circuit structure bonded on the first circuit structure and having a second active area and a second guard ring area, wherein the first circuit structure includes:
a lower insulation layer;
a lower line disposed in the lower insulation layer in the first active area;
a lower guard ring disposed in the lower insulation layer in the first guard ring area; and
a lower insulative bonding layer disposed in the first active area and the first guard ring area, and disposed on the lower insulation layer, wherein the second circuit structure includes:
an upper insulative bonding layer disposed in the second active area and the second guard ring area, and bonded on the lower insulative bonding layer;
an upper insulation layer on the upper insulative bonding layer;
an upper line disposed in the upper insulation layer in the second active area; and
an upper guard ring disposed in the upper insulation layer in the second guard ring area,
wherein the lower insulative bonding layer extends into the first guard ring area between the lower guard ring and the upper guard ring, and
wherein the upper insulative bonding layer extends into the second guard ring area between the lower guard ring and the upper guard ring.

18. The semiconductor device of claim 17, wherein the lower insulative bonding layer fully covers an upper surface of the lower guard ring, and the upper insulative bonding layer fully covers a lower surface of the upper guard ring.

19. A semiconductor device comprising:
a first circuit structure having a first active area and a first guard ring area; and
a second circuit structure bonded on the first circuit structure and having a second active area and a second guard ring area, wherein the first circuit structure includes:
a substrate;
a lower transistor on the substrate;
a lower insulation layer on the substrate and the lower transistor;
a lower line disposed in the lower insulation layer in the first active area;
a lower guard ring disposed in the lower insulation layer in the first guard ring area;
a lower insulative bonding layer disposed in the first active area and the first guard ring area, and disposed on the lower insulation layer; and
a lower bonding pad disposed in the lower insulative bonding layer in the first active area, and connected to the lower line, wherein the second circuit structure includes:
an upper insulative bonding layer disposed in the second active area and the second guard ring area, and bonded on the lower insulative bonding layer;
an upper bonding pad disposed in the upper insulative bonding layer in the second active area, and bonded on the lower bonding pad;
an upper insulation layer on the upper insulative bonding layer;
an upper line disposed in the upper insulation layer in the second active area, and connected to the upper bonding pad;
a stack structure disposed in the upper insulation layer in the second active area;
a channel structure penetrating the stack structure;
a common source line disposed on the stack structure and connected to the channel structure; and
an upper guard ring disposed in the upper insulation layer in the second guard ring area,
wherein the lower insulative bonding layer extends into the first guard ring area between the lower guard ring and the upper guard ring, and
wherein the upper insulative bonding layer extends into the second guard ring area between the lower guard ring and the upper guard ring.

20. The semiconductor device of claim 19, wherein the lower insulative bonding layer fully covers an upper surface of the lower guard ring, and the upper insulative bonding layer fully covers a lower surface of the upper guard ring.
